(19) United States
(12) Patent Application Publication
(10) Pub. No.: US 2003/0193094 A1
(43) Pub. Date: Oct. 16, 2003

(54) Semiconductor device and method for fabricating the same

(75) Inventors: Nobuaki Takahashi, Kanagawa (JP); Kiminori Ishido, Kanagawa (JP); Syuichi Shibazaki, Kanagawa (JP); Kenta Ogawa, Kanagawa (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/410,244

(22) Filed: Apr. 10, 2003

(30) Foreign Application Priority Data
Apr. 12, 2002 (JP) 110042/2002

(51) Int. Cl. H01L 23/48

(52) U.S. Cl. 257/780

(57) ABSTRACT

There is disclosed a fabrication method comprising: stacking and forming an Ni bond layer 3 and oxidation preventive layer 4 on a Cu interconnection layer 2 formed on the surface of a BGA package 1 in an electroless plating process; and applying a flux 5 to coat the oxidation preventive layer 4. Moreover, the method comprises: laying a Cu-added solder ball bump 6 onto the oxidation preventive layer 4; and performing a heat treatment in a temperature range of 190° C. to 220° C. to melt/bond the bump into the Ni bond layer 3. Sn and Cu in the Cu-added solder ball bump 6 rapidly react with Ni in the Ni bond layer 3 to form a diffusion inhibitive alloy layer 7. Subsequently, an electrode pad 10 on a mother board 9 which is a interconnection substrate is molten/bonded into the Cu-added solder ball bump 6, and a semiconductor device 8 is mounted on a mother board 9.

### BACKGROUND OF THE INVENTION

1. Field of the Invention

The present invention relates to a semiconductor device and method for fabricating the device, particularly to a semiconductor device which includes an electrode structure bonded through a solder and method for fabricating the device.

2. Description of the Prior Art

In recent years, it has been well known that performance and function of a semiconductor device for use in portable apparatuses such as a cellular phone have been improved. This semiconductor device includes a constitution having many circuit elements such as a transistor. Moreover, it is a known fact that the semiconductor device is manufactured using a high-precision semiconductor fabrication process.

Furthermore, for a chip size package (CSP) of a semiconductor chip for use in mounting the chip onto the above-described portable apparatus, a mounting area and height need to be reduced and high densification is essential, with miniaturization and sophistication of the apparatus. Furthermore, a multi-chip package (MCP) in which a plurality of semiconductor chips are mounted as one unit is brought into practical use.

Moreover, with rapid spread of information technique, a demand for systemization and sophistication of the semiconductor device constituting an information processing apparatus has increased more and more. Furthermore, there has been an increased expectation for a mounting technique for electronic system integration in which various function blocks including a plurality of silicon semiconductor chips and various function blocks including a semiconductor chip constituted of optical and high-frequency devices using a compound semiconductor are integrated/systemized.

With the above-described densification and sophistication of the semiconductor device, a semiconductor device in which a semiconductor chip including many pins is bonded to a substrate for package by solder bumps, or a semiconductor package including an external terminal of a ball grid array (BGA) type has increased. In the electrode structure of this type of the semiconductor device, by heat history at an assembly time, heat history at a mounting time of the semiconductor package, or high-temperature state or temperature change under a use environment, the constitution of a bond portion interface changes by reaction between metals. A disadvantage is sometimes caused in reliability. It is one of important elements to select materials and form a metal composition in which reliability can be kept against these problems.

The electrode structure in the semiconductor package including the external terminal of the BGA type is described, for example, in Japanese Patent Application Laid-Open No. 10-041303.

Then, as the prior art, the electrode structure in the semiconductor package including the external terminal of the BGA type will be described with reference to FIG. 1. FIG. 1 is a sectional view in order of steps, showing formation of a solder ball bump using a solder of an eutectic composition (Sn: 63 wt (weight) %-Pb: 37 wt %) and connection to a mother board as a interconnection substrate. In the following, in the mounting technique of the semiconductor device, the solder bump for use in the bonding between semiconductor chips, between the semiconductor chip and semiconductor package, and between the semiconductor chip or semiconductor package and interconnection substrate is called a (weld) bond material.

As shown in FIG. 1A, Ni bond layers 103 are formed on Cu interconnection layers 102 on the surface of a BGA package 101 in which the semiconductor chip is disposed by an electroless plating process. Here, an electroless plating solution is usually a chemical obtained by adding reducing agents such as hypophosphorous soda (NaH₂PO₂) to an aqueous solution of nickel salt.

Subsequently, oxidation preventive layers 104 are formed on the Ni bond layers 103. This oxidation preventive layer 104 is constituted of an Au layer formed by the electroless plating process subsequently to the formation of the Ni bond layers 103 by the electroless plating process. Thereafter, fluxes 105 are applied so as to coat the oxidation preventive layers 104.

Next, as shown in FIG. 1B, solder ball bumps 106 are welded and formed. In the welding formation, solder balls are laid on the oxidation preventive layers 104, heat-treated at about 220° C., and welded/bonded to the Ni bond layers 103. In the step of the heat treatment, the oxidation preventive layers 104 constituted of the Au layers are molten in the solder ball bumps 106.

In the above-described step, as shown in FIG. 1B, Sn reacts with Ni in the solder ball bumps 106 to form intermetallic compound layers 107. This intermetallic compound layer 107 is an Ni—Sn intermetallic compound. Furthermore, since Ni diffuses in forming the intermetallic compound layer 107 between the intermetallic compound layer 107 and Ni bond layer 103, P concentrate layers 108 are formed. In this manner, a semiconductor device 109 is completed which includes an electrode structure for connection to a interconnection substrate.

Next, as shown in FIG. 1C, electrode pads 111 on a mother board 110 which is the interconnection substrate are molten and bonded to the solder ball bumps 106, and the semiconductor device 109 is mounted on the mother board. Here, the electrode pads 111 are constituted of Cu.

In the above-described prior-art technique, the solder ball bumps are formed in the electrode structure of a BGA package. Additionally, the solder bumps are molten/bonded onto a interconnection pad formed of aluminum (Al) formed on the semiconductor chip via an Ni bond layer.

However, in the melting/bonding which is broadly used in the existing mounting technique of the semiconductor device and in which solder bump welding is used, as described above, Sn reacts with Ni in the solder ball bumps 106 to form the Ni—Sn intermetallic compound layers 107. In this case, Ni atoms in the Ni bond layers 103 easily and thermally diffuse to form the intermetallic compound layers 107, and are further dissolved in the solder ball bumps 106. Subsequently, the P concentrate layers 108 are formed. Alternatively, thereafter, a coarse region having a low density of Ni atoms is formed. In an extreme case, small voids are generated.

In the prior art, in a step of melting/bonding the solder bumps to the Ni bond layer by the heat treatment for the welding, it is very difficult to control the diffusion of the Ni atoms described above. The heat diffusion of the Ni atoms increases without any limitation. Subsequently, the above-described P concentrate layers 108 or regions having a low density of Ni atoms. In the vicinity of the P concentrate layer 108 or the coarse region, the solder ball bumps 106 are frequently peeled/broken. This is because these regions have brittle physical properties. In this manner, the reliability of the semiconductor package drops. A problem of such drop of the reliability becomes remarkable with the miniaturization and sophistication of the package.

Moreover, the above-described problems occur not only in the semiconductor package but also in a case in which welding/bonding materials such as the solder containing Sn are molten/bonded to the electrode of the interconnection pad on the semiconductor chip via the Ni layer.

### SUMMARY OF THE INVENTION

A main object of the present invention is to provide a melting/bonding technique which has a high reliability in consideration of the above-described problems of a bonding technique of a semiconductor device package. Furthermore, another object of the present invention is to facilitate and promote densification and sophistication of a semiconductor device. To achieve these objects, according to the present invention, there is provided a semiconductor device for use in connecting a semiconductor chip, semiconductor package and interconnection substrate to one another, comprising: an electrode structure which is constituted to hold an Ni diffusion inhibitive layer formed of either one of a nickel (Ni)-copper (Cu)-tin (Sn) intermetallic compound and Ni-palladium (Pd)—Sn intermetallic compound; and a bond material which is bonded to either one of an Ni layer and Ni alloy layer constituting the electrode structure and which is formed of Sn-containing solder constituting the electrode structure. Here, either one of Cu and Pd is added to solder.

Moreover, according to the present invention, an addition amount of either one of Cu and Pd is in a range of 0.1 wt % to 0.5 wt %. Here, solder includes Pb—Sn-base alloy solder, and Pb-free solder such as Sn—Cu-base, Sn—Ag-base, and Sn—Zn-base solder.

Furthermore, in the present invention, solder is Pb—Sn alloy solder of an eutectic composition, and the addition amount of Cu is in a range of 0.2 wt % to 0.3 wt %. Here, the bond material is in the form of either one of a bump and ball bump.

Additionally, in the present invention, the Ni diffusion inhibitive layer is formed in a step of melting/bonding the bond material into either one of Ni and Ni alloy layers.

Moreover, according to the present invention, there is provided a method for fabricating a semiconductor device which is a method for fabricating an electrode structure for use in connecting a semiconductor chip, semiconductor package, and interconnection substrate to one another, the method comprising: a step of adding a predetermined amount of either one of Cu and Pd beforehand to a bond material formed of Sn-containing solder constituting the electrode structure; and a step of melting/bonding the bond material to which either one of Cu and Pd is added into either one of an Ni layer and Ni alloy layer constituting the electrode structure. Here, the bond material may also be formed by applying a solder paste onto the electrode structure.

Furthermore, according to the present invention, there is provided a method for fabricating a semiconductor device which is a method for fabricating a semiconductor device including an electrode structure for use in connecting a semiconductor chip, semiconductor package, and interconnection substrate to one another, the method comprising: a step of applying either one of a flux and solder paste containing either one of Cu and Pd onto either one of an Ni layer and Ni alloy layer constituting the electrode structure; and a step of melting/bonding a bond material formed of Sn-containing solder constituting the electrode structure into either one of an Ni layer and Ni alloy layer via either one of the flux and solder paste.

Additionally, in the method for fabricating the semiconductor device of the present invention, an addition amount of Cu or Pd is set to a range of 0.1 wt % to 0.5 wt %. Here, solder includes Pb—Sn-base alloy solders and Pb-free solder such as Sn—Cu-base, Sn—Ag-base, and Sn—Zn-base solder.

Moreover, in the method for fabricating the semiconductor device of the present invention, solder is Pb—Sn alloy solder of an eutectic composition, and the addition amount of Cu is in a range of 0.2 wt % to 0.3 wt %. Here, the bond material is in the form of either one of a bump and ball bump.

Furthermore, according to the present invention, there is provided a method for fabricating a semiconductor device which is a method for fabricating an electrode structure for use in connecting a semiconductor chip, semiconductor package, and interconnection substrate to one another, the method comprising: a step of coating the surface of an Sn-containing solder ball with a Cu layer; and a step of melting/bonding the solder ball coated with the Cu layer into either one of an Ni layer and Ni alloy layer constituting the electrode structure.

Additionally, according to the present invention, there is provided a method for fabricating a semiconductor device which is a method for fabricating an electrode structure for use in connecting a semiconductor chip, semiconductor package, and interconnection substrate to one another, the method comprising: a step of pressing/attaching a solder tape in which a Cu layer and solder layer are stacked onto either one of an Ni layer and Ni alloy layer constituting the electrode structure to punch the solder tape with a punch; and a step of performing a heat treatment after the punching step to melt/bond the solder tape into either one of the Ni layer and Ni alloy layer.

Moreover, according to the present invention, there is provided a method for fabricating a semiconductor device which is a method for fabricating an electrode structure for use in connecting a semiconductor chip, semiconductor package, and interconnection substrate to one another, the method comprising: a step of forming a stacked plating layer formed of a Cu plating layer and solder plating layer on either one of an Ni layer and Ni alloy layer constituting the electrode structure; and a step of performing heat treatment to melt/bond the stacked plating layer into either one of the Ni layer and Ni alloy layer.

Furthermore, according to the present invention, there is provided a method for fabricating a semiconductor device which is a method for fabricating an electrode structure for use in connecting a semiconductor chip, semiconductor package, and interconnection substrate to one another and in which fabrication of the electrode structure comprises: a step of forming a Cu layer and porous Ni layer in this order; and a step of laying a solder ball on the surface of the Ni layer and performing a heat treatment to melt/bond the solder ball into the Ni layer.

Here, either one of the Ni layer and Ni alloy layer is formed in an electroless plating process in either one of an electroless Ni—P plating solution and electroless Ni—B plating solution.

In the present invention, in the step of melting/bonding the Sn-containing bond material into either one of the Ni layer and Ni alloy layer in the electrode structure, heat movement of an Ni atom toward the bond material is stopped by a Ni diffusion inhibitive layer. Moreover, formation of a brittle layer described in the prior art is inhibited.

Therefore, bond strength of either one of the Ni layer and Ni alloy layer in the electrode structure to the bond material is enhanced. Furthermore, a peel/breakage ratio of the bond material from the electrode structure is largely reduced.

In this manner, reliability of the packaged semiconductor device is enhanced, and densification or sophistication of the semiconductor device is facilitated.

### BRIEF DESCRIPTION OF THE DRAWINGS

FIG. 1A depicts a schematic sectional view in order of steps of solder ball bump formation and semiconductor device mounting according to a prior art;

FIG. 1B depicts a schematic sectional view following FIG. 1A in order of the steps of the solder ball bump formation and semiconductor device mounting;

FIG. 1C depicts a schematic sectional view following FIG. 1B in order of the steps of the solder ball bump formation and semiconductor device mounting;

FIG. 2A depicts a schematic sectional view in order of the steps of the solder ball bump formation and semiconductor device mounting according to a first embodiment of the present invention;

FIG. 2B depicts a schematic sectional view following FIG. 2A in order of the steps of the solder ball bump formation and semiconductor device mounting;

FIG. 2C depicts a schematic sectional view following FIG. 2B in order of the steps of the solder ball bump formation and semiconductor device mounting;

FIG. 3 depicts a graph showing an adhesion strength after the melting/bonding to describe an effect of the present invention;

FIG. 4 depicts a graph showing a breakage ratio after the melting/bonding to describe the effect of the present invention;

FIG. 5A depicts a schematic sectional view in order of the steps of the solder ball bump formation and semiconductor device mounting according to a second embodiment of the present invention;

FIG. 5B depicts a schematic sectional view following FIG. 5A in order of the steps of the solder ball bump formation and semiconductor device mounting;

FIG. 5C depicts a schematic sectional view following FIG. 5B in order of the steps of the solder ball bump formation and semiconductor device mounting;

FIG. 6A depicts a schematic sectional view in order of the steps of the solder ball bump formation and semiconductor device mounting according to a third embodiment of the present invention;

FIG. 6B depicts a schematic sectional view following FIG. 6A in order of the steps of the solder ball bump formation and semiconductor device mounting;

FIG. 6C depicts a schematic sectional view following FIG. 6B in order of the steps of the solder ball bump formation and semiconductor device mounting;

FIG. 7 depicts a schematic sectional view showing a forming method of a solder bump according to a fourth embodiment of the present invention;

FIG. 8 depicts a schematic sectional view showing a forming method of the solder bump according to a fifth embodiment of the present invention;

FIG. 9A depicts a schematic sectional view in order of the steps of the solder ball bump formation and semiconductor device mounting according to a sixth embodiment of the present invention;

FIG. 9B depicts a schematic sectional view following FIG. 9A in order of the steps of the solder ball bump formation and semiconductor device mounting; and

FIG. 10 depicts a schematic sectional view showing the forming method of the solder bump according to a seventh embodiment of the present invention.

### DETAILED DESCRIPTION OF THE PREFERRED EMBODIMENTS

Next, a semiconductor integrated circuit of an embodiment of the present invention will be described in detail with reference to the drawings.

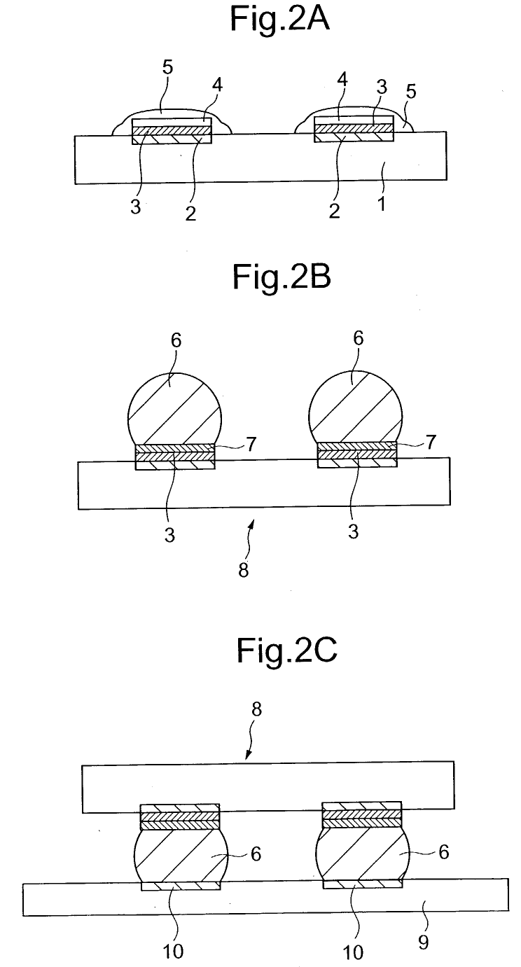

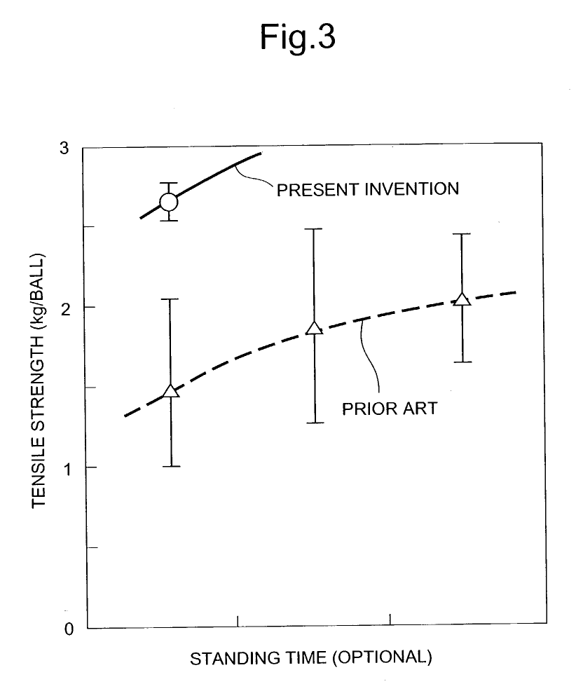

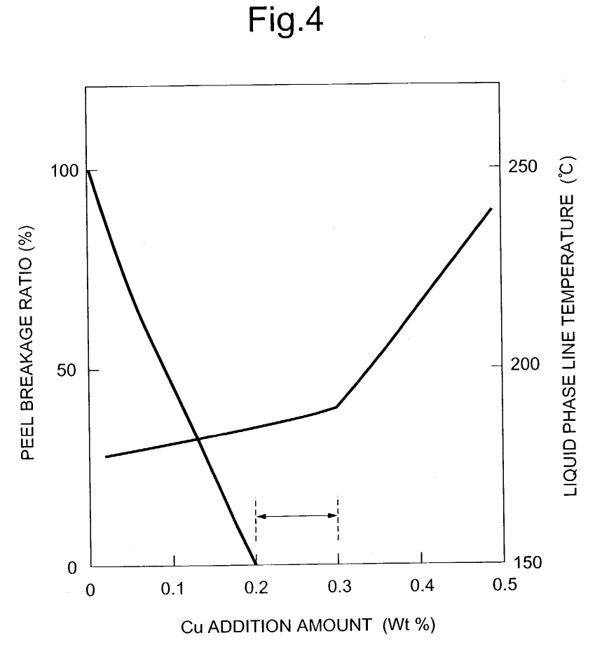

First, a first embodiment of the present invention will be described with reference to FIGS. 2 to 4. FIG. 2 depicts a sectional view of a step order, showing formation of a solder ball bump of a BGA package using Pb—Sn alloy solder (tin-lead solder) of an eutectic composition in the present invention and connection to a mother board which is a interconnection substrate. The present invention is characterized in that a micro amount of Cu atoms are added to the solder ball bump. Moreover, FIGS. 3 and 4 depicts graphs showing an effect generated in this case. Here, a semiconductor chip is mounted on the BGA package.

In the same manner as described in the prior art, as shown in FIG. 2A, Ni bond layers 3 are formed on Cu interconnection layers 2 formed on the surface of a BGA package 1 in an electroless plating process. Here, an electroless plating solution is a chemical obtained by adding reducing agents such as hypophosphorous soda (NaH₂PO₂) to an aqueous solution of nickel salt. Moreover, the Ni bond layers 3 and oxidation preventive layers 4 are stacked and formed. Thereafter, fluxes 5 are applied to coat the oxidation preventive layers 4.

Next, as shown in FIG. 2B, Cu-added solder ball bumps 6 are welded/formed. This formation comprises: laying a solder ball having a diameter of about 700 μmφ on the oxidation preventive layer 4; performing a heat treatment in a temperature range of 190° C. to 220° C.; and melting/bonding the ball into the Ni bond layer 3. Here, an Au atom of the oxidation preventive layer 4 is molten in the Cu-added solder ball bump 6.

In the heat treatment step, as shown in FIG. 2B, Sn and Cu in the Cu-added solder ball bumps 6 rapidly react with Ni in the Ni bond layers 3 to form diffusion inhibitive alloy layers 7. This diffusion inhibitive alloy layer 7 is an intermetallic compound formed of Ni—Cu—Sn. Different from the prior art, the diffusion inhibitive alloy layers 7 formed of Ni—Cu—Sn have a function of inhibiting heat diffusion of Ni atoms as described later.

Therefore, the formation of P concentrate layers described in the prior art is largely reduced. In this manner, a semiconductor device 8 is completed which includes an electrode structure for connection to a interconnection substrate.

Next, as shown in FIG. 2C, electrode pads 10 on a mother board 9 which is the interconnection substrate are molten/bonded to the Cu-added solder ball bumps 6, and the semiconductor device 8 is mounted on the mother board 9. Here, the electrode pads 10 are formed of Cu.

Next, an effect of the present invention will be described. In FIG. 3, a test sample is prepared in which the melting/bonding of the electrode pads on the mother board into the Cu-added solder ball bumps of the BGA package is simulated, and a change of bond strength with time is checked. In this test sample, 25 ball bumps laid within a square are molten/bonded in a Cu plate.

An ordinate of FIG. 3 indicates a tensile strength per solder ball obtained with the test sample. Moreover, an abscissa indicates a room-temperature standing time of the test sample. As shown in FIG. 3, in the present invention, the tensile strength becomes 1.5 times or more that of the prior art. That is, it has been seen that an adhesion force after the welding of the Ni bond layers 3 to the Cu-added solder ball bumps 6 is largely enhanced.

Furthermore, the test sample is used to study peel/breakage of the ball bump formed of solder of the eutectic composition while changing the addition amount of Cu. Here, the breakage is checked, after the test sample is allowed to stand at room temperature for a predetermined time.

For FIG. 4, a left ordinate indicates a peel breakage ratio, and an abscissa indicates the Cu addition amount in wt %. Moreover, a right ordinate indicates a liquid phase line temperature in ° C. In this case, the liquid phase line temperature indicates a boundary line between a region in which solid and liquid phases of solder are mixed at a time of change of the Cu addition amount and a region in which only the liquid phase exists in a state diagram.

As shown in FIG. 4, the breakage ratio rapidly decreases with an increase of the Cu addition amount, and turns to zero with the Cu addition amount of 0.2 wt % or more. Moreover, as seen from FIG. 4, the liquid phase line temperature rapidly rises, when the Cu addition amount exceeds 0.3 wt %. In the welding of the solder ball bumps, the solder balls need to be partially in a liquid phase state. Moreover, the state becomes preferable at a lower temperature. This is necessary from a viewpoint of heat resistance of a resin or organic adhesive constituting a package.

The present invention becomes very effective for the above-described reason, when the Cu-added solder ball bumps obtained by adding Cu to solder of the eutectic composition by 0.2 wt % to 0.3 wt % are used.

Then, the inventor performed physical analysis of a bond portion of the solder ball bump. That is, the portion was analyzed by energy dispersive X-ray microscopy (EDX) and secondary electron microscopy (SEM) of the intermetallic compound layer and diffusion inhibitive alloy layer.

As a result, in the present invention, it has been seen that the diffusion inhibitive alloy layer 3 is constituted of Ni—Cu—Sn. Moreover, it has been seen that the Ni atoms are stopped by the diffusion inhibitive alloy layer 3 and hardly enter the solder ball bump region.

Furthermore, in the present invention, the diffusion inhibitive alloy layer 3 is easily uniformly formed between the Ni bond layer 3 and Cu-added solder ball bump 6. Here, the diffusion inhibitive alloy layer 3 has a thickness of 1 μm to 2 μm, and about 0.1 wt % in the Cu-added solder ball bump forms the intermetallic compound formed of Ni—Cu—Sn described above.

In this manner, it has been clarified that the diffusion inhibitive alloy layer 3 having the above-described function can easily be formed in the present invention and therefore a large effect is generated in enhancement of the adhesion force and reduction of the peel breakage ratio.

On the other hand, the intermetallic compound layer formed in the prior art is constituted of Ni—Sn as described above, and the formed layer disperses and is not uniform with a bond portion different from the present invention. Moreover, the Ni—Sn intermetallic compound does not have a function of diffusion inhibition of Ni. It has been clarified that the intermetallic compound layer formed in the prior art does not have a function of inhibiting the Ni atoms from being diffused.

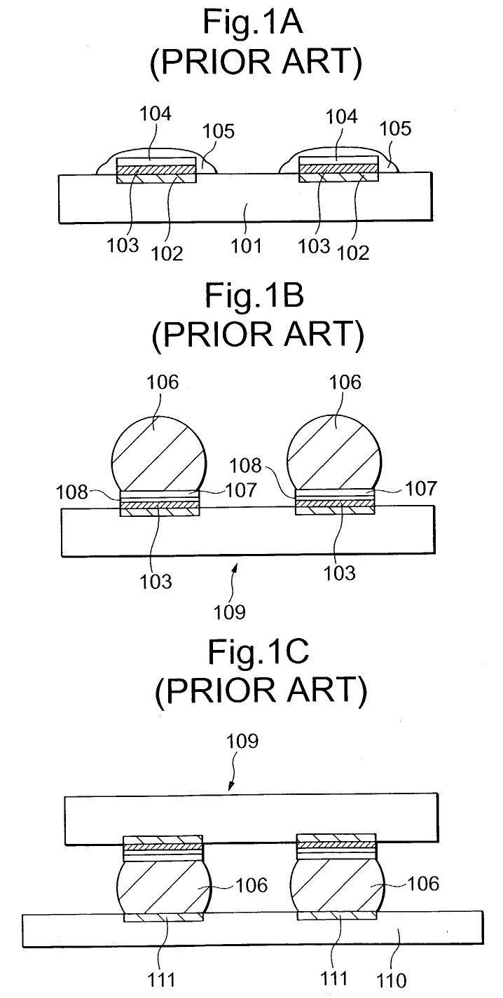

Furthermore, the phenomenon will be described in detail. In the prior art, in the stage of FIG. 1B, only the Ni—Sn intermetallic compound is formed. Moreover, in the stage of FIG. 1C, since Cu of the electrode pad 111 of the mother board 110 thermally diffuses, an Ni—Cu—Sn intermetallic compound is also formed in addition to the Ni—Sn intermetallic compound. However, since the Ni—Cu—Sn intermetallic compound is formed in a non-uniform distribution (the whole surface is not uniformly coated), the Ni—Cu—Sn intermetallic compound does not have a function of inhibiting Ni from thermally diffusing. These are causes of the problem generated in the prior art.

The first embodiment is a case in which tin-lead solder of the eutectic composition is used as the material (weld material) of the weld/bond material essential for the mounting of the semiconductor device. The present inventor prepared the test sample with respect to the other weld material, performed various basic studies, and added the above-described physical analysis. Here, as the weld material, tin-lead solder of a composition other than the eutectic composition, and lead-free solder containing a main component of Sn were used. Here, as lead-free solder, Sn—Cn-base, Sn—Ag-base, and Sn—Zn-base were studied. Moreover, Cu or Pd was added to these weld materials, the material was molten/bonded into the Ni bond layer, and peel breakage and adhesion force were evaluated.

As a result, it has been found that the adhesion force is enhanced and the peel breakage ratio is reduced by the addition of Cu or Pd in all of the above-described weld materials.

When an amount of Cu or Pd to be added to the weld material is increased, the above-described effect increases. However, conversely, the liquid phase line temperature described with reference to FIG. 4 rises. In this case, at present, there has not been sufficient data with respect to the peel breakage ratio in the test sample. However, it has been found that the addition amount of Cu or Pd may be set to 0.1 wt % or more in consideration of the dispersion of the peel breakage.

Moreover, the addition amount of Cu or Pd may be set not to exceed 0.5 wt % in consideration of the liquid phase line temperature. If the amount exceeds 0.5 wt %, a melt bond temperature rises, and a resin or organic adhesive for sealing is deteriorated. Therefore, when solder containing another main component of Sn is used as the weld material, the addition amount of Cu or Pd is preferably set in a range of 0.1 wt % to 0.5 wt %.

In the above-described embodiment, the solder bump which is the weld bond material has been described, but the present invention can also be applied to the use of the solder paste as the weld bond material. It is to be noted that the Sn—Bi-base and Sn—Sb-base also exist as solder free of lead. However, it can be considered from the above-described basic study that even with the application of the present invention to any base, the similar effect is produced.

Moreover, in the embodiment, as described above, in the formation of the electrode structure for use in connecting the semiconductor chip, semiconductor package, and interconnection substrate to one another, the bond material formed of Sn-containing solder is bonded to the Ni layer or Ni alloy layer via the Ni diffusion inhibitive layer constituted of the Ni—Cu—Sn intermetallic compound or Ni—Pd—Sn intermetallic compound.

From the result of the basic study, the present invention is not limited to this case. A certain semiconductor chip is bonded/connected to the Ni layer or Ni alloy layer on another semiconductor chip, semiconductor package, or interconnection substrate via the bond material having the electrode structure. Even in this case, the similar effect is produced.

Alternatively, even when the semiconductor package is bonded and connected to the Ni layer, Ni alloy layer, or Cu layer on the interconnection substrate via the bond material including the above-described electrode structure, the similar effect is produced.

In this case, the bond material formed of tin-lead solder of the eutectic composition may contain 0.2 wt % to 0.3 wt % of Cu. Alternatively, the bond material formed by solder containing the main component of Sn other than the above main contain 0.1 wt % to 0.5 wt % of Cu or Pd.

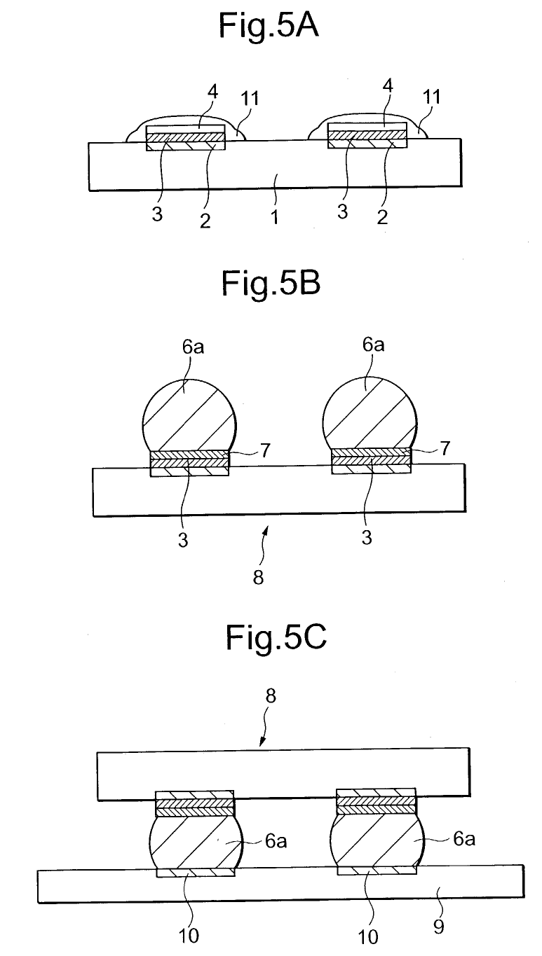

Next, a second embodiment of the present invention will be described with reference to FIG. 5. FIG. 5 depicts a sectional view of the step order showing the connection of the BGA package to the mother board in a case in which the present invention is applied to the formation of the solder bump formed of tin-lead solder. In the present embodiment, a micro amount of Cu atoms are added into the flux.

As shown in FIG. 5A, in the same manner as in the first embodiment, the Ni bond layers 3 are formed on the Cu interconnection layers 2 formed on the surface of the BGA package 1 by the electroless plating process. Moreover, the diffusion inhibitive alloy layers 3 and oxidation preventive layers 4 are stacked and formed. Thereafter, Cu-added fluxes 11 are applied so as to coat the oxidation preventive layers 4. Here, as the flux, the rosin-base flux or organic-base flux is used. The main components of the rosin flux may be an abietic acid, repopimaric acid, and dehydroabetic acid. An Micro powder copper or organic compound of copper is added to this flux to form the Cu-added flux 11. Here, the Cu addition amount is set to be higher than that described in the first embodiment, but the Cu addition amount may be in a range of 0.1 wt % to 0.5 wt %.

Next, the solder balls are laid on the Cu-added fluxes 11, thermally treated at about 220° C., and molten/bonded. In this manner, Cu in the Cu-added flux 11 is molten in the solder ball, and Cu-added solder ball bumps 6a are formed as shown in FIG. 5B. Here, Au atoms of the oxidation preventive layers 4 are also molten into the solder ball bumps.

In the heat treatment step, as shown in FIG. 5B, Sn and Cu in the generated Cu-added solder ball bumps 6a rapidly react with Ni in the diffusion inhibitive alloy layers 3 to form the diffusion inhibitive alloy layers 7. The diffusion inhibitive alloy layers 7 are intermetallic compounds formed of Ni—Cu—Sn. In the same manner as in the first embodiment, the diffusion inhibitive alloy layers 7 formed of Ni—Cu—Sn have a function of inhibiting heat diffusion of Ni atoms. Therefore, the formation of the P concentrate layers described in the prior art is largely reduced. In this manner, the semiconductor device 8 is completed which includes the electrode structure for the connection to the interconnection substrate. Moreover, as shown in FIG. 5C, the electrode pads 10 on the mother board 9 which is the interconnection substrate are molten/bonded to the Cu-added solder ball bumps 6a, and the semiconductor device 8 is mounted on the mother board 9. In this case, as described in the first embodiment, the effects of the enhancement of the adhesion force and reduction of the peel breakage ratio are produced.

In this embodiment, even when the Cu-added solder paste is used instead of the Cu-added flux, the device can similarly be formed.

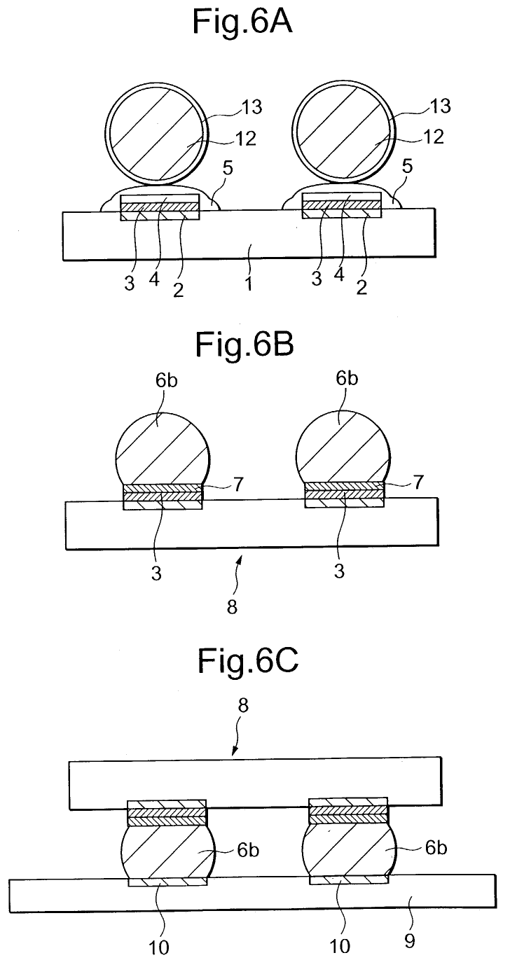

Next, a third embodiment of the present invention will be described with reference to FIG. 6. FIG. 6 depicts a sectional view of the step order showing the connection to the mother board in a case in which the present invention is applied to the formation of the solder bump using tin-lead solder. In the present embodiment, a Cu coating layer is formed on the surface of the solder ball.

As shown in FIG. 6A, in the same manner as in the first embodiment, the Ni bond layers 3 and oxidation preventive layers 4 are stacked and formed on the Cu interconnection layers 2 formed on the surface of the BGA package 1 by the electroless plating process. Thereafter, the fluxes 5 are applied so as to coat the oxidation preventive layers 4.

Next, Cu coating layers 13 formed on the surfaces of solder balls 12 are used and laid on the fluxes 5, heat-treated at about 220° C., and molten/bonded.

In this manner, Cu in the Cu coating layers 13 is molten in the solder balls 12, and Cu-added solder ball bumps 6b are formed as shown in FIG. 6B. Here, the solder balls 12 have a diameter of about 800 μmφ. Moreover, the thickness of the Cu coating layer 13 is controlled to indicate a predetermined value.

In the heat treatment step, as shown in FIG. 6B, Sn and Cu in the generated Cu-added solder ball bumps 6b rapidly react with Ni in the Ni bond layers 3 to form the diffusion inhibitive alloy layers 7. The diffusion inhibitive alloy layers 7 are the intermetallic compounds formed of Ni—Cu—Sn. In the same manner as in the first embodiment, the diffusion inhibitive alloy layers 7 formed of Ni—Cu—Sn have a function of inhibiting the heat diffusion of the Ni atoms. In this manner, the semiconductor device 8 is completed which includes the electrode structure for the connection to the interconnection substrate. Moreover, as shown in FIG. 6C, the electrode pads 10 on the mother board 9 which is the interconnection substrate are molten/bonded to the Cu-added solder ball bumps 6b, and the semiconductor device 8 is mounted on the mother board 9.

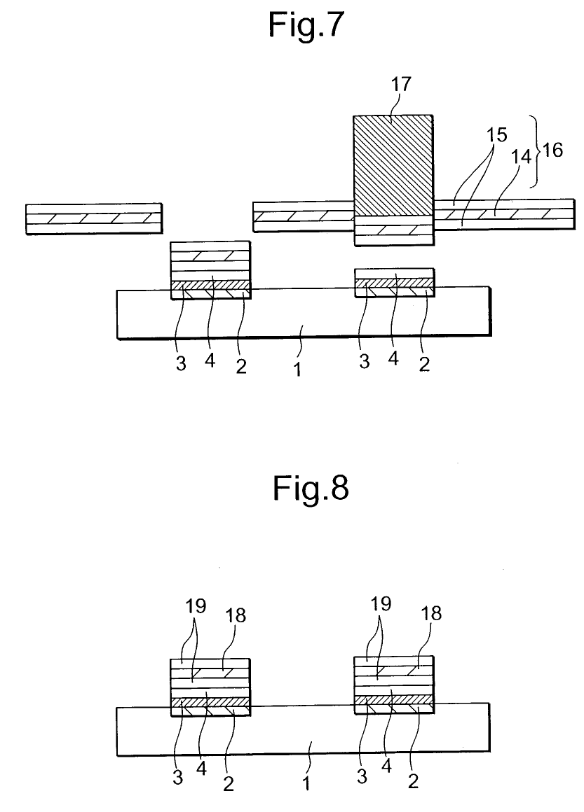

Next, a fourth embodiment of the present invention will be described with reference to FIG. 7. FIG. 7 depicts a partial sectional view showing another forming method of the Cu-added solder bumps, which is the characteristic of the present invention.

As shown in FIG. 7, in the same manner as in the first embodiment, the Ni bond layers 3 and oxidation preventive layers 4 are stacked and formed on the Cu interconnection layers 2 formed on the surface of the BGA package 1 by the electroless plating process.

Moreover, as shown in FIG. 7, the method comprises: coating BGA package 1 with a solder tape 16 in which a solder layer 14 is vertically coated with Cu layers 15 in a sandwich form; positioning a punch 17 with respect to the Cu interconnection layer 2; punching the solder tape 16 with the punch 17; and pressing/attaching the tape to the oxidation preventive layers 4 on the Cu interconnection layers 2.

As not shown, thereafter, in the same manner as in the first embodiment, the heat treatment is performed at about 220° C. and the melting/bonding is performed. In this manner, Cu of the Cu layers 15 is molten in the solder layer 14. Additionally, Sn and Cu in the solder layer 14 rapidly react with Ni in the Ni bond layers 3 to form the diffusion inhibitive alloy layers. In this manner, the effects of the enhancement of the adhesion force and reduction of the peel breakage ratio are produced as described in the first embodiment.

Next, a fifth embodiment of the present invention will be described with reference to FIG. 8. FIG. 8 depicts also a partial sectional view showing another forming method of the Cu-added solder bumps, which is the characteristic of the present invention.

As shown in FIG. 8, in the same manner as in the first embodiment, the Ni bond layers 3 and oxidation preventive layers 4 are formed on the Cu interconnection layers 2 formed on the surface of the BGA package 1, and further solder plating layers 18 and Cu plating layers 19 are stacked and formed by the electroless plating process.

Moreover, as not shown, thereafter, in the same manner as in the first embodiment, the heat treatment is performed at about 220° C. and the melting/bonding is performed. In this manner, Cu of the Cu plating layers 19 is molten in the solder plating layers 18. Additionally, Sn and Cu in the solder plating layers 18 rapidly react with Ni in the Ni bond layers 3 to form the diffusion inhibitive alloy layers.

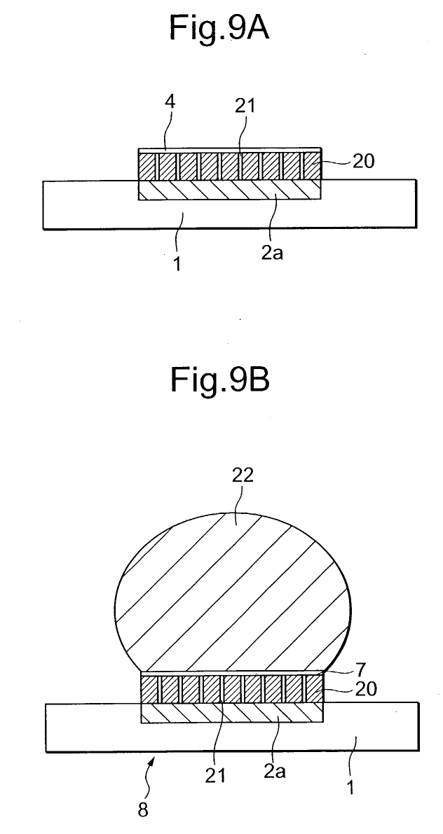

Next, a sixth embodiment of the present invention will be described with reference to FIG. 9. FIG. 9 is a sectional view of the step order in a case in which the present invention is applied to the formation of the solder bumps using tin-lead solder. In the present embodiment, the Cu atoms can be supplied to the solder balls from the Cu interconnection layer.

As shown in FIG. 9A, in the same manner as in the first embodiment, a porous Ni bond layer 20 is formed on a Cu interconnection layer 2a formed on the surface of the BGA package 1 by the electroless plating process. Here, a large number of micro holes 21 are formed in the porous Ni bond layer 20. Subsequently, the oxidation preventive layer 4 is stacked and formed on the porous Ni bond layer 20.

Thereafter, the flux (not shown) is applied to coat the oxidation preventive layer 4, the solder ball is laid on the flux, the heat treatment is performed at about 220° C., and the melting/bonding is performed. In this heat treatment, Cu in the Cu interconnection layer 2a passes through the holes 21 and diffuses in the surface of the porous Ni bond layer 20. Subsequently, as shown in FIG. 9B, a solder ball bump 22 is formed. Here, the Au atoms of the oxidation preventive layer 4 are molten into the solder ball bump 22.

Subsequently, Sn in the solder ball bump 22, Cu which has diffused from the Cu interconnection layer 2a, and Ni of the porous Ni bond layer 20 rapidly react with one another to form the diffusion inhibitive alloy layer 7. The diffusion inhibitive alloy layer 7 is the intermetallic compound formed of Ni—Cu—Sn. In the same manner as in the first embodiment, the diffusion inhibitive alloy layer 7 formed of Ni—Cu—Sn has a function of inhibiting the heat diffusion of the Ni atoms. In this manner, the semiconductor device 8 is completed which includes the electrode for the connection to the interconnection substrate.

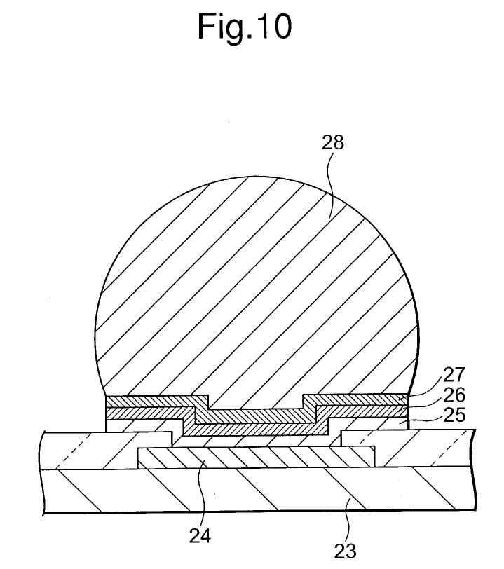

In the above-described embodiment, the solder ball bump which is the weld bond material is formed on the electrode of the BGA package. Next, a case in which the solder ball bump is molten/bonded into a interconnection pad formed of Al formed on the semiconductor chip via the Ni bond layer will be described as a seventh embodiment with reference to FIG. 10.

A interconnection pad 24 on a semiconductor substrate 23 is usually formed of aluminum or aluminum alloy. An adhesive layer 25 is formed of titanium or titanium/tungsten alloy. Subsequently, an Ni bond layer 26 is formed on the adhesive layer 25 by the electroless plating process or sputtering process. Here, the Ni bond layer 26 may also be formed on the interconnection pad 24 by the electroless plating process without forming the adhesive layer 25.

Next, as not shown, in the same manner as described with reference to FIG. 8, after stacking/forming two layers including a solder plating layer and Cu plating layer, the heat treatment is performed at about 200° C., and the melting/bonding is performed. In this manner, Cu in the Cu plating layer is molten into the solder plating layer. Additionally, Sn and Cu in the solder plating layer rapidly react with Ni in the Ni bond layer 26 to form a diffusion inhibitive alloy layer 27. Subsequently, a Cu-added solder bump 28 can further be formed on the semiconductor chip 23. In this case, the Cu-added solder bump 28 has a diameter of about 100 μmφ.

Even in this case, in the same manner as in the first embodiment, the effects of the enhancement of the adhesion force between the Ni bond layer 26 and Cu-added solder bump 28 and the reduction of the peel breakage ratio in this region are produced.

In the embodiment of the present invention described above, as described in the basic study of the first embodiment, Pd may also be used instead of Cu, and lead-free solder may also be applied as an adhesion material to solder containing the main component of Sn.

In the above-described embodiment of the present invention, the electroless plating solution for use forming the Ni bond layer by the electroless plating process is a chemical obtained by adding reducing agents such as hypophosphorous soda (NaH₂PO₂) to the aqueous solution of nickel salt, that is, the electroless Ni—P plating solution. The present invention is not limited to the electroless plating solution. The present invention can similarly be applied even to a case in which the chemical obtained by adding the reducing agents such as boron-hydrogenated soda (NaBH₄) to the aqueous solution of nickel salt, that is, the electroless Ni—B plating solution is used as the electroless plating solution for use in forming the Ni bond layer by the electroless plating process.

Moreover, in the above-described embodiment, the melting/bonding of the Ni bond layer to the solder bump containing the component of Sn has been described, but the present invention can also be applied even to a case in which the Ni bond layer is constituted of the Ni alloy. Here, the Ni alloy includes a nickel/vanadium alloy, nickel/phosphor alloy, nickel/titanium alloy, nickel/chromium alloy, and nickel/copper alloy. These Ni alloy layers can easily be formed by the sputtering process.

In the above-described embodiments of the present invention, the diffusion inhibitive alloy layer is formed in the step of melting/bonding the bond materials such as the solder bump into the Ni bond layer constituting the electrode structure. The present invention is not limited to this. The Ni—Cu(Pd)—Sn alloy layer may be formed on the Ni bond layer by the sputtering process before the melting/bonding.

The present invention is not limited to the above-described embodiments, and the embodiments can appropriately be changed within the scope of the technical thought of the present invention.

In the constitution of the present invention described above, in the electrode structure for mounting the semiconductor device, when the Sn-containing bond material is molten/bonded into the Ni layer or Ni alloy layer constituting the electrode structure, the movement of the heat of the Ni atoms in the Ni layer or Ni alloy layer toward the bond material is stopped by the generated Ni diffusion inhibitive layer. Therefore, the brittle layer is inhibited from being generated by the movement of the Ni atoms.

Moreover, the adhesion strength of the Ni layer or Ni alloy layer in the electrode structure to the bond material is enhanced. Furthermore, the peel breakage ratio from the electrode structure of the bond material is largely reduced.

In this manner, the reliability of the packaged semiconductor device is largely enhanced, and the densification of sophistication of the semiconductor device is promoted.

What is claimed is:

1. A semiconductor device for use in connecting a semiconductor chip, semiconductor package and interconnection substrate to one another, comprising:
an electrode structure which is constituted to hold an Ni diffusion inhibitive layer formed of either one of a nickel (Ni)-copper (Cu)-tin (Sn) intermetallic compound and Ni-palladium (Pd)—Sn intermetallic compound; and
a bond material which is bonded to either one of an Ni layer and Ni alloy layer constituting the electrode structure and which is formed of Sn-containing solder constituting the electrode structure.

2. The semiconductor device according to claim 1, wherein either one of Cu and Pd is added to solder.

3. The semiconductor device according to claim 2, wherein an addition amount of either one of Cu and Pd is in a range of 0.1 wt (weight) % to 0.5 wt %.

4. The semiconductor device according to claim 2, wherein solder comprises lead (Pb)—Sn-base alloy solder, Pb-free solder such as Sn—Cu-base, Sn-silver (Ag)-base, and Sn-zinc (Zn)-base solder, and any one of Sn—Cu-base, Sn-silver (Ag)-base, and Sn-zinc (Zn)-base solder.

5. The semiconductor device according to claim 3, wherein solder comprises lead (Pb)—Sn-base alloy solder, Pb-free solder such as Sn—Cu-base, Sn-silver (Ag)-base, and Sn-zinc (Zn)-base solder, and any one of Sn—Cu-base, Sn-silver (Ag)-base, and Sn-zinc (Zn)-base solder.

6. The semiconductor device according to claim 3, wherein solder is Pb—Sn alloy solder of an eutectic composition, and the addition amount of Cu is in a range of 0.2 wt % to 0.3 wt %.

7. The semiconductor device according to claim 1, wherein the bond material is in the form of either one of a bump and ball bump.

8. The semiconductor device according to claim 1, wherein the Ni diffusion inhibitive layer is formed in a step of melting/bonding the bond material into either one of Ni and Ni alloy layers.

9. The semiconductor device according to claim 1, wherein one semiconductor chip is bonded and connected to either one of Ni and Ni alloy layers on either one of another semiconductor chip, semiconductor package, and interconnection substrate via the bond material which includes the electrode structure.

10. The semiconductor device according to claim 1, wherein the semiconductor package is bonded and connected to any one of Ni, Ni alloy, and Cu layers on the interconnection substrate via the bond material which includes the electrode structure.

11. A fabrication method for a semiconductor device comprising an electrode structure for use in connecting a semiconductor chip, semiconductor package, and interconnection substrate to one another, the method comprising:
a step of adding a predetermined amount of either one of Cu and Pd beforehand to a bond material formed of Sn-containing solder constituting the electrode structure; and a step of melting/bonding the bond material to which either one of Cu and Pd is added into either one of Ni and Ni alloy layers constituting the electrode structure.

12. A fabrication method for a semiconductor device comprising an electrode structure for use in connecting a semiconductor chip, semiconductor package, and interconnection substrate to one another, the method comprising:
a step of applying either one of a flux and solder paste containing either one of Cu and Pd onto either one of Ni and Ni alloy layers constituting the electrode structure; and a step of melting/bonding a bond material formed of Sn-containing solder constituting the electrode structure into either one of Ni and Ni alloy layers via either one of the flux and solder paste.

13. The fabrication method for the semiconductor device according to claim 11, wherein the bond material is formed by applying a solder paste onto the electrode structure.

14. The fabrication method for the semiconductor device according to claim 11, wherein an addition amount of either one of Cu and Pd is in a range of 0.1 wt % to 0.5 wt %.

15. The fabrication method for the semiconductor device according to claim 11, wherein solder comprises Pb—Sn-base alloy solder, and Pb-free solder such as Sn—Cu-base, Sn—Ag-base, and Sn—Zn-base solder.

16. The fabrication method for the semiconductor device according to claim 11, wherein solder is Pb—Sn alloy solder of an eutectic composition, and the addition amount of Cu is in a range of 0.2 wt % to 0.3 wt %.

17. The fabrication method for the semiconductor device according to claim 11, wherein the bond material is in the form of either one of a bump and ball bump.

18. A fabrication method for a semiconductor device comprising an electrode structure for use in connecting a semiconductor chip, semiconductor package, and interconnection substrate to one another, the method comprising:
a step of coating the surface of an Sn-containing solder ball with a Cu layer; and a step of melting/bonding the solder ball coated with the Cu layer into either one of Ni and Ni alloy layers constituting the electrode structure.

19. A fabrication method for a semiconductor device comprising an electrode structure for use in connecting a semiconductor chip, semiconductor package, and interconnection substrate to one another, the method comprising:
a step of pressing/attaching a solder tape in which a Cu layer and solder layer are stacked onto either one of Ni and Ni alloy layers constituting the electrode structure to punch the solder tape with a punch; and a step of performing a heat treatment after the punching step to melt/bond the solder tape into either one of the Ni and Ni alloy layers.

20. A fabrication method for a semiconductor device comprising an electrode structure for use in connecting a semiconductor chip, semiconductor package, and interconnection substrate to one another, the method comprising:
a step of forming a stacked plating layer formed of a Cu plating layer and solder plating layer on either one of Ni and Ni alloy layers constituting the electrode structure; and a step of performing a heat treatment to melt/bond the stacked plating layer into either one of the Ni and Ni alloy layers.

21. A fabrication method for a semiconductor device comprising an electrode structure for use in connecting a semiconductor chip, semiconductor package, and interconnection substrate to one another, the method comprising:
a step of stacking and forming a Cu layer and porous Ni layer in this order in the electrode structure; and a step of laying a solder ball on the surface of the Ni layer and performing a heat treatment to melt/bond the solder ball into the Ni layer.

22. The fabrication method for the semiconductor device according to claim 11, wherein either one of the Ni and Ni alloy layers is formed in an electroless plating process in either one of an electroless Ni-phosphor (P) plating solution and electroless Ni-boron (B) plating solution.
